(19) United States
(12) Patent Application Publication
(10) Pub. No.: US 2014/0004668 A1
(43) Pub. Date: Jan. 2, 2014

(54) METHOD FOR MANUFACTURING NITRIDE ELECTRONIC DEVICES

(71) Applicants: Yu Saitoh, Itami-shi (JP); Masaya Okada, Osaka-shi (JP); Makoto Kiyama, Itami-shi (JP)

(72) Inventors: Yu Saitoh, Itami-shi (JP); Masaya Okada, Osaka-shi (JP); Makoto Kiyama, Itami-shi (JP)

(73) Assignee: Sumitomo Electric Industries, Ltd., Osaka-shi (JP)

(21) Appl. No.: 14/006,307

(22) PCT Filed: Apr. 5, 2011
(86) PCT No.: PCT/JP2011/058639

§ 371 Date: Sep. 19, 2013

(51) Int. Cl. H01L 29/66

(52) U.S. Cl. CPC H01L 29/66431
USPC 438/172

(57) ABSTRACT

A substrate product is disposed in a growth furnace at time t0, and the substrate temperature is then raised to 950° C. At time t3 after the substrate temperature is sufficiently stable, trimethyl gallium and ammonia are supplied to the growth furnace, to grow an i-GaN film. The substrate temperature reaches 1080° C. at time t5. At time t6 after the substrate temperature is sufficiently stable, trimethyl gallium, trimethyl aluminum and ammonia are supplied to the growth furnace, to grow an i-AlGaN film. Supply of trimethyl gallium and trimethyl aluminum is stopped at time t7 to discontinue film deposition. Quickly thereafter, supply of ammonia and hydrogen to the growth furnace is stopped and supply of nitrogen is initiated, to change the atmosphere of ammonia and hydrogen in a growth furnace chamber to a nitrogen atmosphere. After formation of the nitrogen atmosphere, the substrate temperature starts being lowered at time t8.

### TECHNICAL FIELD

The present invention relates to a method for manufacturing nitride electronic devices.

### BACKGROUND ART

Patent Document 1 discloses a semiconductor device. This semiconductor device has good electric properties and exhibits improved pinch-off-angle characteristics or enhanced channel layer mobility.

### CITATION LIST

### Patent Literature

Patent Document 1: Japanese Patent Application Publication No. 2006-286941

### SUMMARY OF INVENTION

### Technical Problem

Manufacturing a transistor having the configuration of Patent Document 1 involves forming an epitaxial growth stack in which an n⁻-type GaN layer, a p-type GaN layer and an n⁺-type GaN layer are epitaxially grown, in this order, on a conductive substrate, and then etching, on a main surface of the epitaxial growth stack, an opening section that extends from the n⁺-type GaN layer to the n⁻-type GaN layer. On the side surface of this opening, an i-type GaN layer and an i-type AlGaN layer are formed in this order. A gate insulating film and a gate electrode are formed on the i-type GaN layer and the i-type AlGaN layer on the opening section side surface. The surface state of the side surface of the opening section that is formed by etching is not as good as that of the main surface of the epitaxial growth stack, on account of the manufacturing method of the transistor having the configuration of Patent Document 1.

According to findings by the inventors, an inclined surface is formed on the underlying epitaxial growth stack, and the i-type GaN layer and i-type AlGaN layer for a hetero structure are regrown thereafter. During this regrowth, surface defects occur in the regrown semiconductor layer, on the side surface of the opening section, due to the influence of the inclination and surface planarity. In this device structure, these surface defects give rise to a gate leakage current, both in a manufacturing method that involves forming a gate electrode after formation of a gate insulating film on the inclined surface, and in a manufacturing layer that involves directly forming a gate electrode on the regrown layer.

It is thus an object of the present invention to provide a method for manufacturing nitride electronic devices that allows reducing gate leakage current.

### Solution to Problem

The invention according to an aspect of the present invention is method for manufacturing nitride electronic devices. This method comprises the steps of (a) forming a substrate product by arranging a substrate in a growth furnace, and thereafter, supplying a source gas containing ammonia and a group III element to the growth furnace, to thereby grow, at a growth temperature, a carrier supply layer on a channel layer on a main surface of the substrate; (b), exposing the substrate product to a predetermined atmosphere at a temperature not higher than the growth temperature after growth of the carrier supply layer is complete; (c) lowering the temperature of the substrate product in the predetermined atmosphere, and removing thereafter the substrate product from the growth furnace; and (d) forming a gate electrode on the carrier supply layer after removing the substrate product. The channel layer includes a first portion and a second portion, the first portion extends along a first reference plane that is inclined with respect to the main surface of the substrate and a plane perpendicular to a c-axis of the gallium nitride-based semiconductor of the channel layer, and the second portion extends along a second reference plane that is inclined with respect to the first portion; the carrier supply layer includes a first portion and a second portion, the first portion is grown on the first portion of the channel layer, and the second portion is grown on the second portion of the channel layer; the gate electrode is formed on the first portion of the carrier supply layer; an angle formed by a first axis perpendicular to the first reference plane and the c-axis of the gallium nitride-based semiconductor is larger than an angle formed by a second axis perpendicular to the second reference plane and the c-axis of the gallium nitride-based semiconductor; the band gap of the group III nitride semiconductor of the carrier supply layer is larger than the band gap of the gallium nitride-based semiconductor of the channel layer; the predetermined atmosphere contains nitrogen but no ammonia; the channel layer includes a gallium nitride-based semiconductor; and the carrier supply layer includes a group III nitride semiconductor.

In the present method, the first portion of the channel layer extends along a first reference plane that is inclined with respect to both the main surface of the substrate and a plane that is perpendicular to the c-axis of the gallium nitride-based semiconductor of the channel layer. The second portion of the channel layer is inclined with respect to the first portion. Accordingly, the first and second portions of the channel layer have mutually dissimilar surface orientations. The first and second portions of the carrier supply layer are respectively grown on the first and second portions of the channel layer. The angle formed by the c-axis of the gallium nitride-based semiconductor and the first axis is larger than the angle formed by the c-axis of the gallium nitride-based semiconductor and the second axis. Therefore, surface migration of the constituent elements at the growth surface is inactive during growth on the first portion of the channel layer and the carrier supply layer. As a result, the mode of growth on the first portions tends to be an island growth mode. In growth according to this mode, the final surface morphology is rough, and as a result defects are introduced into the crystal surface. The abovementioned surface defects give rise to gate leakage currents when the gate electrode is formed on the first portion of the carrier supply layer. In this method, a process is carried out wherein the substrate product is exposed to a temperature not higher than a growth temperature, in a predetermined atmosphere, after completion of growth of the carrier supply layer prior to formation of the gate electrode on the first portion of the carrier supply layer. In this process, the predetermined atmosphere contains nitrogen but does not contain ammonia. Therefore, it becomes possible to reduce surface defects that are caused by the inclination and/or the surface planarity of the carrier supply layer and the first portion of the channel layer, through modification of the surface of the first portion of the carrier supply layer. The predetermined atmosphere promotes migration after growth at the surface of the carrier supply layer, and allows improving surface planarity thereby. Accordingly, it becomes possible to reduce gate leakage current caused by surface defects.

The manufacturing method according to an aspect of the present invention may farther comprise the steps of: (e) forming a semiconductor stack by growing, on the main surface of the substrate, a drift layer formed of a first gallium nitride-based semiconductor, a current block layer formed of a second gallium nitride-based semiconductor and a contact layer formed of a third gallium nitride-based semiconductor; (f) forming an opening in a main surface of the semiconductor stack by dry etching; and (g) growing the channel layer on the main surface of the semiconductor stack and on the opening of the semiconductor stack. The opening has a side surface that is inclined with respect to the main surface of the semiconductor stack; the side surface of the opening includes a side surface of the drift layer, a side surface of the current block layer and a side surface of the contact layer; the first portion of the channel layer is grown on the side surface of the opening; the second portion of the channel layer is grown on the main surface of the semiconductor stack; the conductivity type of the second gallium nitride-based semiconductor is different from the conductivity type of the first gallium nitride-based semiconductor; the gate electrode is formed on the side surface of the current block layer; and the conductivity type of the second gallium nitride-based semiconductor is different from the conductivity type of the third gallium nitride-based semiconductor.

In this manufacturing method, crystal regrowth for the channel layer and carrier supply layer is influenced by the surface planarity of an underlying opening side surface. The channel layer and the carrier supply layer are grown on the opening side surface, and the opening side surface is formed by dry etching. The roughness in the surface state of the opening side surface is accordingly large. The surface of the first portion of the channel layer and the carrier supply layer is influenced by the underlying roughness. In the above processes of the present method, the predetermined atmosphere contains nitrogen but does not contain ammonia. Therefore, it becomes possible to reduce as well surface roughness caused by etching, through modification of the surface of the first portion of the carrier supply layer. Accordingly, it becomes possible to reduce gate leakage current caused by surface defects.

In the manufacturing method according to an aspect of the present invention, a material of each of the channel layer and the carrier supply layer may be any one from among InGaN/AlGaN, GaN/AlGaN and AlGaN/AlN. A suitable combination of channel layer and carrier supply layer is thus provided in this manufacturing method.

The manufacturing method according to an aspect of the present invention may further comprise the step of (h) forming the predetermined atmosphere in the growth furnace while maintaining the temperature of the substrate product at the growth temperature after growth of the carrier supply layer is complete. The temperature of the substrate product may start being lowered from the growth temperature, after the predetermined atmosphere is provided in the growth furnace.

Through formation of the predetermined atmosphere in the growth furnace, the present manufacturing method allows preventing the outermost surface from being exposed to ammonia for a long period of time. If the atmosphere after crystal growth is over contains ammonia, the nitrogen atoms from ammonia that decomposes in the growth furnace become adsorbed on the outermost surface, and hamper surface migration of the group III atoms. When the atmosphere after crystal growth contains nitrogen but not ammonia, the group III atoms, which have a vapor pressure lower than that of nitrogen, remain on the outermost surface. The group III atoms remain at a moderate density, on the outermost surface.

Temperature lowering is elicited in the predetermined atmosphere, and hence it becomes possible to achieve a technical contribution of surface modification also during temperature lowering. Nitrides decompose more actively in a nitrogen atmosphere than in an ammonia atmosphere. Temperature lowering allows preventing group III atoms from decomposing out of the outermost surface by exceeding a desired amount.

In the manufacturing method according to an aspect of the present invention, the substrate may be formed of a conductive free-standing group III nitride substrate. Preferably, a main surface of the free-standing group III nitride substrate is at −20 degrees to +20 degrees with respect to a c-axis of a group III nitride of the substrate, from the viewpoint of planarity after epitaxial growth. The method may further comprise the step of forming a drain electrode on a rear surface of the substrate. In this manufacturing method, the above angle range is appropriate for a useful device.

In the manufacturing method according to an aspect of the present invention, preferably, an angle formed by the first reference plane and the second reference plane ranges from 5 degrees to 40 degrees. In this manufacturing method, the above angle range is appropriate for a useful device.

In the manufacturing method according to an aspect of the present invention, the first gallium nitride-based semiconductor of the drift layer, the second gallium nitride-based semiconductor of the current block layer, and the third gallium nitride-based semiconductor of the contact layer may be any one from among n-type GaN/p-type GaN/n⁺-type GaN and n-type GaN/p-type AlGaN/n⁺-type GaN. A suitable combination of drift layer, current block layer and contact layer is provided in this manufacturing method.

The manufacturing method according to an aspect of the present invention may further comprise the step of forming a source electrode on the main surface of the semiconductor stack after the substrate product is removed. The source electrode may supply potential to the current block layer and the contact layer; the channel layer and the carrier supply layer may form a junction; a two-dimensional electron gas layer may be formed in the junction; and the source electrode may supply carriers that flow through the channel layer. In this manufacturing method, the source electrode supplies potential to the current block layer and the contact layer, and hence the current block layer functions as a back gate of the channel layer.

In the manufacturing method according to an aspect of the present invention, the gate electrode may form a junction with the first portion of the carrier supply layer. This manufacturing method allows providing a transistor in which channel carriers are controlled using a gate electrode that forms a Schottky junction with a semiconductor.

The manufacturing method according to an aspect of the present invention may further comprise the steps of: forming a gate insulating film on the first portion of the carrier supply layer; and forming a gate electrode on the gate insulating film. The gate electrode forms a junction with the gate insulating film. This manufacturing method allows providing a transistor having the gate electrode that controls channel carriers via the insulating film.

In the manufacturing method according to an aspect of the present invention, the gate insulating film may be grown by atomic layer deposition (ALD). This manufacturing method can contribute to further reducing gate leakage, with little damage to an underlying carrier supply layer, upon deposition of the gate insulating film.

The abovementioned object as well as other objects, features and advantages of the present invention will be made apparent more easily on the basis of the detailed description of preferred embodiments of the present invention as set forth below with reference to accompanying drawings.

### Advantageous Effects of Invention

As explained above, the present invention provides a method for manufacturing nitride electronic devices that allows reducing gate leakage current.

### BRIEF DESCRIPTION OF DRAWINGS

FIG. 1 is a process flow diagram illustrating a main process in a method for manufacturing a nitride electronic device, an epitaxial substrate and a substrate product according to an embodiment of the present invention;

FIG. 2 is a set of diagrams illustrating schematically a process of a manufacturing method according to an embodiment of the present invention;

FIG. 3 is a set of diagrams illustrating schematically a process of a manufacturing method according to an embodiment of the present invention;

FIG. 4 is a set of diagrams illustrating schematically a process of a manufacturing method according to an embodiment of the present invention;

FIG. 5 is a set of diagrams illustrating schematically a process of a manufacturing method according to an embodiment of the present invention;

FIG. 6 is diagram illustrating schematically a nitride electronic device according to an embodiment of the present invention;

FIG. 7 is a set of diagrams illustrating a temperature modification sequence during regrowth;

FIG. 8 is a set of diagrams illustrating scanning electron micrographs of an epitaxial regrowth surface of a substrate product; and

FIG. 9 is a set of diagrams illustrating measurements of gate-drain current leakage in a transistor manufactured in an example.

### DESCRIPTION OF EMBODIMENTS

The findings of the present invention can be easily grasped by referring to the below-described detailed description and accompanying exemplary drawings. An explanation follows next, with reference to accompanying drawings, on embodiments of a method for manufacturing a nitride electronic device, an epitaxial substrate and a substrate product of the present invention. Whenever possible, identical portions will be denoted with identical reference numerals.

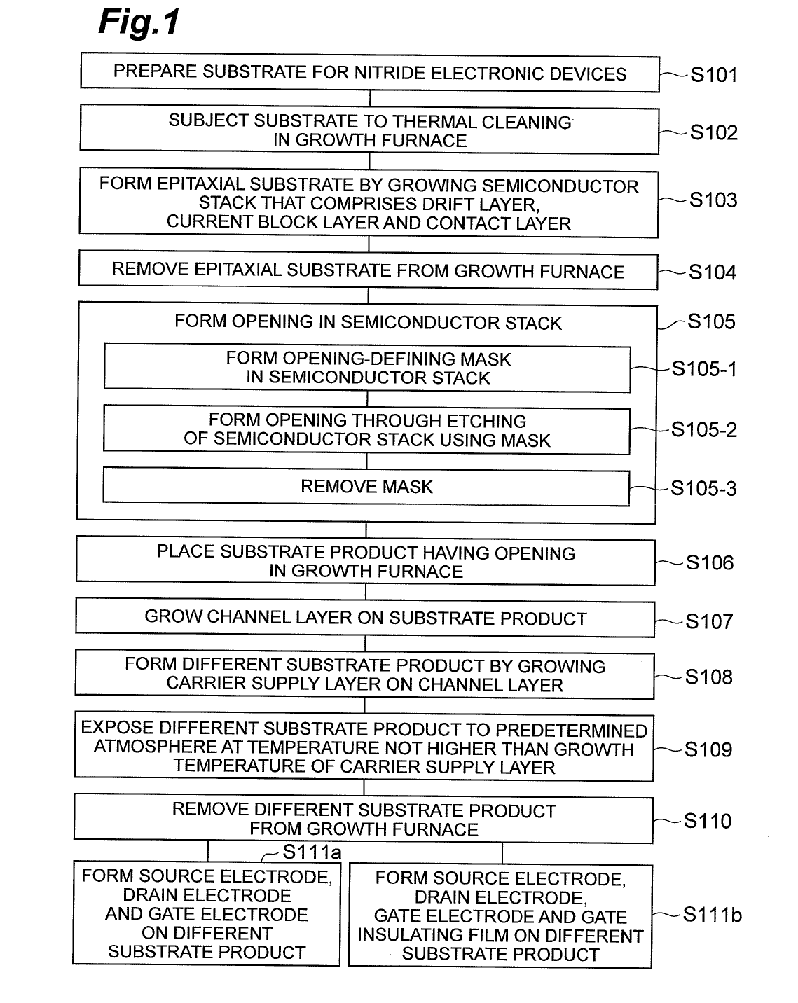

FIG. 1 is a process flow diagram illustrating a main process in a method for manufacturing a nitride electronic device, an epitaxial substrate and a substrate product according to an embodiment of the present invention.

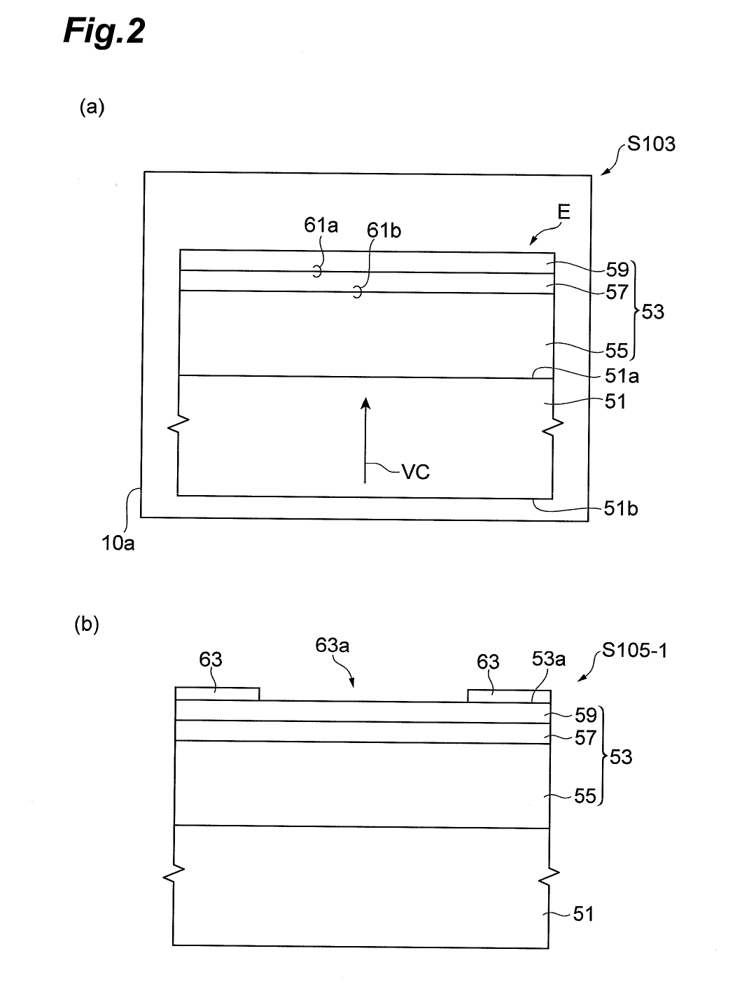

In step S101, a substrate for a nitride electronic device is prepared. The substrate, which exhibits conductivity, can be formed of, for instance, a hexagonal-system group III nitride. A free-standing group III nitride semiconductor substrate (hereafter, denoted by the reference numeral “51” in Part (a) of FIG. 2) can be formed of, for instance, GaN, AN or the like. The substrate 51 has a main surface 51a and a rear surface 51b. In a suitable example, the main surface 51a of the group III nitride semiconductor substrate 51 can be constituted by a c-plane, but can have a slight off-angle with respect to the c-axis of the group III nitride of the substrate, for instance an off-angle ranging from −20 degrees to +20 degrees. The above angle range is useful in a device. In Part (a) of FIG. 2, a c-axis vector VC denotes the c-axis direction.

In step S102, the group III nitride semiconductor substrate 51 is disposed in a growth furnace (denoted by the reference numeral “10a” in Part (a) of FIG. 2), and the group III nitride semiconductor substrate 51 is then subjected to thermal cleaning. Thermal cleaning is carried out through thermal treatment of the group III nitride semiconductor substrate 51 in an atmosphere that contains, for instance, ammonia and hydrogen. The thermal treatment lasts, for instance, for about 10 minutes. The thermal treatment temperature is, for instance, of about 1030° C. The pressure in the furnace is, for instance, 100 Torr.

In step S103, a semiconductor stack 53 is grown on the main surface 51a of the substrate 51, to form an epitaxial substrate E, as illustrated in Part (a) of FIG. 2. In the formation of the semiconductor stack 53, a drift layer 55 formed of a first conductivity type gallium nitride-based semiconductor, a current block layer 57 formed of a second conductivity type gallium nitride-based semiconductor and a contact layer 59 for the first conductivity type gallium nitride-based semiconductor are grown, in this order, on the main surface 51a of the substrate 51. Growth is accomplished herein, for instance, by metalorganic chemical vapor deposition. The drift layer 55 is formed of, for instance, 5 μm-thick undoped GaN, the current block layer 57 is formed of, for instance, 0.5 μm-thick Mg-doped p-type GaN, and the contact layer 59 is formed of, for instance, 0.2 μm-thick Si-doped n⁺-type GaN. The surface orientation of junctions 61a, 61b in the semiconductor stack 53 is identical to the surface orientation of the main surface 51a of the substrate 51. In this case, the thickness of the semiconductor stack 53 is 5.7 μm.

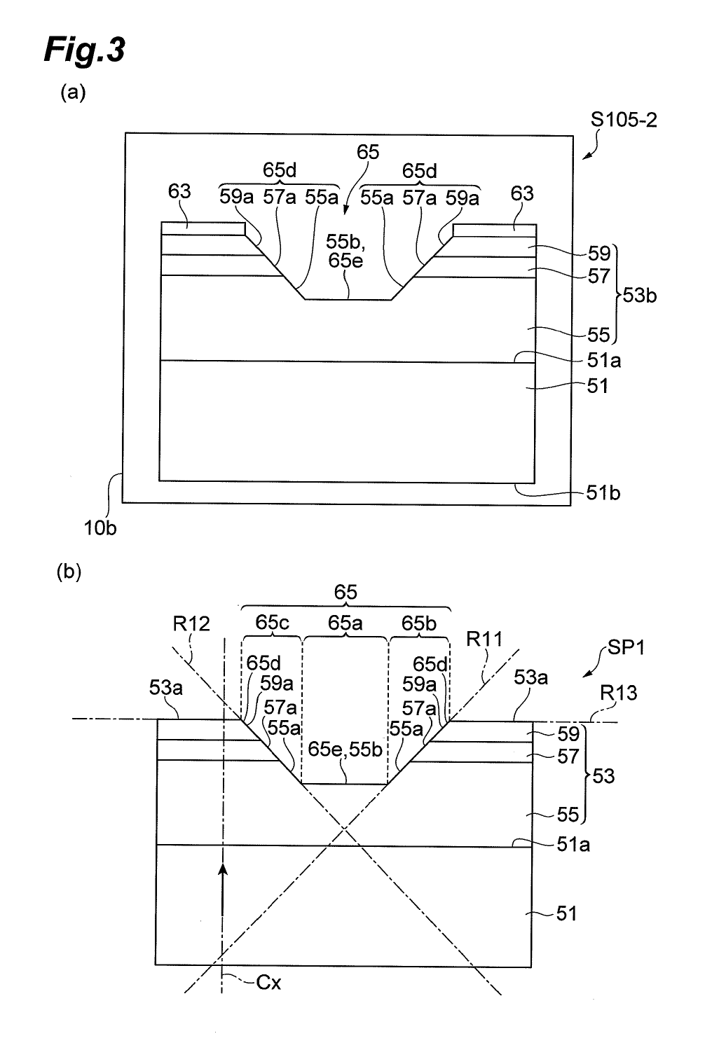

In step S104, the epitaxial substrate E is removed from the growth furnace 10a. Thereafter, in step S105, an opening is formed in the semiconductor stack 53. Firstly, in step S105-1, a mask 63 is formed on a surface 53a of the semiconductor stack 53 by photolithography, as illustrated in Part (b) of FIG. 2. The mask 63 can be formed of, for instance, a resist or a silicon oxide film. The mask 63 has an opening 63a that defines the shape and position of the opening that is to be formed in the semiconductor stack 53. After the mask 63 has been formed by photolithography, the epitaxial substrate E is disposed, in step S105-2, in an etching equipment 10b illustrated in Part (a) of FIG. 3. The semiconductor stack 53 is dry-etched using this equipment 10b and the mask 63. Dry etching may be, for instance, reactive ion etching (RIE). Chlorine gas can be used as the etchant. An opening 65 is formed in the semiconductor stack 53 through etching using the mask 63. A semiconductor stack 53b including the opening 65 becomes formed as a result of opening formation.

The opening 65 reaches from the contact layer 59 of the surface 53a to the drift layer. The opening 65 is defined by side surfaces 65d and a bottom surface 65e. Side surfaces 55a and a top surface 55b of the drift layer 55, side surfaces 57a of the current block layer 57, and side surfaces 59a of the contact layer 59 appear on the side surfaces 65d of the opening 65. The top surface 55b of the drift layer 55 appears on the bottom surface 65e of the opening 65.

In step S105-3, the mask 63 is removed, as illustrated in Part (b) of FIG. 3. A substrate product SP1 becomes formed as a result. In the substrate product SP1, the opening 65 has first through third portions 65a, 65b, 65c. The top surface 55b (bottom surface 65e) of the drift layer 55 is exposed in the first portion 65a. In the second portion 65b and the third portion 65c, the side surfaces 65d of the opening 65 extend obliquely from the top surface 55b of the drift layer 55 up to the surface 53a of the semiconductor stack 53b.

In Part (b) of FIG. 3, a single opening 65 is depicted, but the substrate 51 has multiple openings arrayed thereon. Accordingly, the semiconductor stack 53b takes on a mesa shape, or a shape including a recess (for instance, a groove) in accordance with the shape of the opening 63. The side surfaces 65d are inclined with respect to the main surface 51a of the substrate 51, and are inclined with respect to the surface 53a of the semiconductor stack 53b. The specific inclination angle of the side surfaces 65d can be controlled through etching.

One of the side surfaces 65d extends, over the entirety thereof, along a reference plane R11, and the other side surface 65d extends, over the entirety thereof, along a reference plane R12. The reference planes R11, R12 are inclined with respect to the main surface 51a of the substrate 51 and a reference axis Cx that denotes the direction of the c-axis of the group III nitride substrate 51. The normal lines of the reference planes R11, R12 are inclined with respect to the c-axis, and the main surface 53a of the semiconductor stack 53b extends along a reference plane R13. The angle formed by the c-axis and the normal lines of the reference planes R11, R12 is larger than the angle formed by the c-axis and the normal line of the reference plane R13. In a suitable example, the main surface 53a of the semiconductor stack 53b can be substantially parallel to the main surface 51a of the substrate 51. The angle formed by the reference planes R11, R12 (i.e. the side surfaces 65d) and the reference plane R13 (main surfaces 63a, 51a) can range, for instance, from 5 degrees to 40 degrees.

If necessary, a pre-treatment (for instance, cleaning) of the substrate product SP1 is performed prior to the growth of a channel layer and a carrier supply layer, and the substrate product SP1 is disposed thereafter in the growth furnace 10a, in step S106.

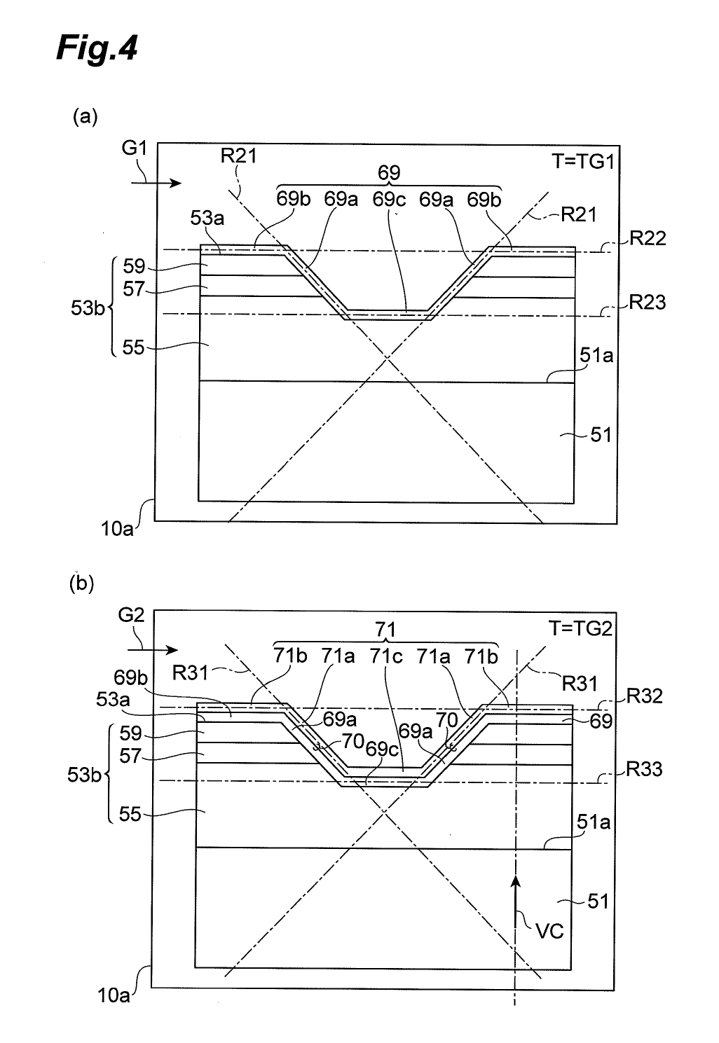

In step S107, a source gas G1 that contains ammonia and a group III element material is supplied to the growth furnace 10a, to thereby grow a channel layer 69, at a growth temperature TG1, on the main surface 53a of the semiconductor stack 53b and on the side surfaces 65d and the bottom surface 65e of the opening 65, as illustrated in Part (a) of FIG. 4. The channel layer 69 is formed of a gallium nitride-based semiconductor. The channel layer 68 includes first portions 69a, second portions 69b and a third portion 69c. The first portions 69a are grown on the side surfaces 65d of the opening 65, and extend along reference planes R21. The reference planes R21 are inclined with respect to the main surface 51a of the substrate 51 and to a plane that is perpendicular to the c-axis of the gallium nitride-based semiconductor of the channel layer 69. The second portions 69b are grown on the main surface 53a of the semiconductor stack 53b, and extend along a reference plane R22 that is perpendicular to the c-axis. The first portions 69a are inclined with respect to the reference plane R22. The third portion 69c is grown on the bottom surface 65e of the opening 65, and extends along a reference plane R23. The first portions 69a are inclined with respect to the reference plane R23. In a suitable example, the reference plane R23 is substantially parallel to the reference plane R22, and the reference plane R23 and the reference plane R22 are parallel to the main surface 51a of the substrate 51.

In step S108, a source gas G2 that contains ammonia and a group III element material is supplied to the growth furnace 10a, to thereby grow a carrier supply layer 71, at a growth temperature TG2, on the main surface 53a of the semiconductor stack 53b and on the side surfaces 65d and the bottom surface 65e of the opening 65, as illustrated in Part (b) of FIG. 4. The carrier supply layer 71 forms a heterojunction 70 with the channel layer 69. The carrier supply layer 71 is formed of a group III nitride semiconductor. The carrier supply layer 71 includes first portions 71a, second portions 71b and a third portion 71c. The first portions 71a are grown on the side surfaces 65d of the opening 65, and extend along reference planes R31. The reference planes R31 are inclined with respect to main surface 51a of the substrate 51 and a plane that is perpendicular to the c-axis of the gallium nitride-based semiconductor of the carrier supply layer 71 (in the same direction as the c-axis of the substrate 51). The second portions 71b are grown on the main surface 53a of the semiconductor stack 53b, and extend along a reference plane R32. The first portions 71a are inclined with respect to the reference plane R32. The third portion 71c is grown on the bottom surface 65e of the opening 65, and extends along a reference plane R33. The first portions 71a are inclined with respect to the reference plane R33. In the present example, the reference plane R33 is substantially parallel to the reference plane R32, and the reference plane R33 and the reference plane R32 are parallel to the main surface 51a of the substrate 51. The band gap of the group III nitride semiconductor of the carrier supply layer 71 is larger than the band gap of the gallium nitride-based semiconductor of the channel layer 69.

A first angle formed by a first axis that is perpendicular to one of the reference planes R31, and the c-axis of the gallium nitride-based semiconductor of the carrier supply layer 71, is larger than a second angle formed by a second axis perpendicular the reference plane R32, and the c-axis of the gallium nitride-based semiconductor of the carrier supply layer 71. The second angle is zero or a very small angle when the main surface 51a of the substrate 51 has a c-plane or slight off-angle from the c-plane. The first angle corresponds to the inclination of the side surfaces 65d of the opening 65, and is larger than the second angle. The inclination of the first portions 69a, 71a is accordingly substantial.

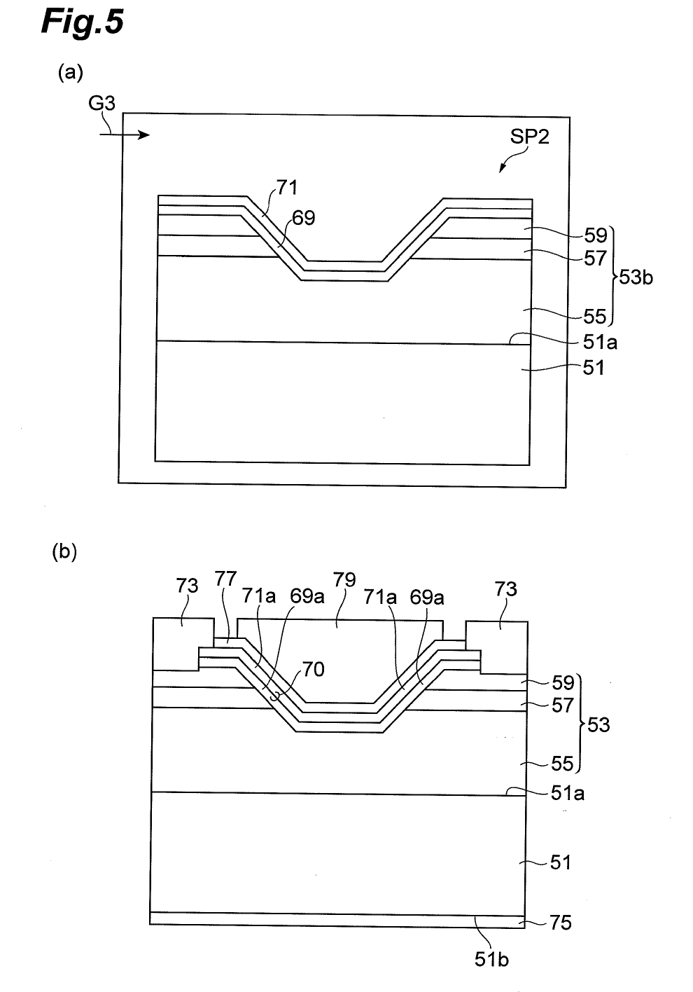

In step S109, after growth of the carrier supply layer 71 is complete, the surfaces 71a of the carrier supply layer 71 are exposed to a predetermined atmosphere G3 at a temperature not higher than the growth temperature TG2 of the carrier supply layer 71, as illustrated in Part (a) of FIG. 5. The predetermined atmosphere contains nitrogen (N₂) but does not contain ammonia.

After growth of the carrier supply layer 71 is complete, preferably, the predetermined atmosphere is formed in the growth furnace 10a, while maintaining the temperature of a substrate product SP2 at the growth temperature TG2. The temperature of the substrate product SP2 can start being lowered from the growth temperature TG2 after supply of the predetermined atmosphere to the growth furnace 10a. Through formation of the predetermined atmosphere in the growth furnace 10, the present manufacturing method allows preventing the outermost surface of the substrate product SP2 from being exposed to ammonia for a long period of time. If the atmosphere after crystal growth contains ammonia, the nitrogen atoms from ammonia that decomposes in the growth furnace 10a become adsorbed on the outermost surface of the substrate product SP2, and hamper surface migration of the group III atoms. When the atmosphere after crystal growth contains nitrogen but not ammonia, by contrast, the group III atoms, which have a vapor pressure lower than that of nitrogen, remain on the outermost surface. The group III atoms remain at a moderate density, on the outermost surface.

Temperature lowering is elicited in the predetermined atmosphere, and hence it becomes possible to achieve a technical contribution of surface modification not only during the period of the growth temperature TG2 but also during temperature lowering. Nitrides decompose more actively in a nitrogen atmosphere than in an ammonia atmosphere. Temperature lowering allows preventing group III atoms from decomposing out of the outermost surface by exceeding a desired amount.

After the temperature of the substrate product SP2 is lowered and the substrate product SP1 is removed, the substrate product SP2 is removed, in step S110, from the growth furnace 10a, as illustrated in Part (b) of FIG. 5. In the electrode formation process of step S111a or step S111b, a gate electrode is formed on the carrier supply layer 71. In the electrode formation process, more specifically, there is formed a source electrode 73 that forms a contact with the semiconductor layers 57, 59 of the semiconductor stack 53b, there is formed a drain electrode 75 which forms a contact with the rear surface 51b of the substrate 51, there is formed a gate insulating film 77, and there is formed a gate electrode 79 which forms a contact on the gate insulating film 77.

For instance, the gate insulating film 77 can be grown by atomic layer deposition (ALD). This manufacturing method can contribute to further reducing gate leakage, with little damage to the underlying carrier supply layer, upon deposition of the gate insulating film 77.

The source electrode can be formed on the main surface 53a of the semiconductor stack 53b. The source electrode 73 supplies potential to the current block layer 57 and the contact layer 59. The channel layer 69 and the carrier supply layer 71 form the junction 70, such that a two-dimensional carrier gas layer is formed in the junction 70. The source electrode 73 supplies carriers that flow through the channel layer 69. The carriers flow towards the drift layer 55 via the two-dimensional carrier gas layer. In this manufacturing method, the source electrode 73 supplies potential to the current block layer 57 and the contact layer 59, and hence the current block layer 57 functions as a back gate for the channel layer 69.

In this method, as illustrated in Part (a) of FIG. 4, the first portions 69a of the channel layer 69 extends along the reference planes R21 that are inclined with respect to the main surface 51a of the substrate 51 and to a plane perpendicular to the c-axis of the gallium nitride-based semiconductor of the first portions 69a. Accordingly, the first and second portions 69a, 69b of the channel layer 69 have mutually dissimilar surface orientations. The first and second portions 71a, 71b of the carrier supply layer 71 are respectively grown on the first and second portions 69a, 69b of the channel layer 69. The side surface 69d of the opening 69 is inclined, and hence during growth on the first portions 69a, 71a of the channel layer 6 and the carrier supply layer 71, surface migration of the constituent elements at the growth surfaces is less active than that during growth at the second portions 69b, 71b. As a result, the mode of growth on the first portions 69a, 71a tends to be an island growth mode. In growth according to this mode, defects are formed on the crystal surface, and the final surface morphology is rough. The abovementioned surface defects give rise to gate leakage currents when the gate electrode 79 is formed on the inclined first portions 71a. In this method, a process is carried out wherein the substrate product SP2 is exposed to a temperature not higher than the growth temperature TG2 in a predetermined atmosphere consisting essentially of nitrogen, after completion of growth of the carrier supply layer 71, prior to formation of the gate electrode 79 on the first portions 71a of the carrier supply layer 71. In this process, the predetermined atmosphere contains nitrogen (N₂) but does not contain ammonia. Therefore, it becomes possible to reduce surface defects that are caused by the inclination and/or the surface planarity of the first portions 71a, 69a of the carrier supply layer 71 and the channel layer 69, through modification of the surface of the first portions 71a of the carrier supply layer 71. The predetermined atmosphere promotes migration after growth at the surfaces 71a of the carrier supply layer 71, and allows improving surface planarity thereby. Accordingly, it becomes possible to reduce gate leakage current caused by surface defects.

In this manufacturing method, crystal regrowth for the channel layer 69 and carrier supply layers 71 is influenced by the surface planarity of the underlying opening side surfaces 65d. The channel layer 69 and the carrier supply layer 71 are grown on the opening side surfaces 65d, and the opening side surfaces 65d are formed by dry etching. The roughness in the surface state of the opening side surfaces 65d is accordingly large. The surface of the first portions 69a, 71a of the channel layer 69 and the carrier supply layer 71 is influenced by the underlying roughness. In the above process, the predetermined atmosphere contains nitrogen (N₂) but does not contain ammonia. Therefore, it becomes possible to reduce as well surface roughness caused by etching, through modification of the surface of the first portions 71a of the carrier supply layer 71. Accordingly, it becomes possible to reduce gate leakage current caused by surface defects. Growth is carried out through a continued set of growth runs from the channel layer 69 to the carrier supply layer 71; as a result, this allows forming a clean heterojunction and improving the planarity of the surface of the carrier supply layer in a predetermined atmosphere. The present embodiment, moreover, allows reducing current collapse.

In the present embodiment, the gate insulating film 77 is formed on the first portions 71a of the carrier supply layer 71, after which the gate electrode 79 can be formed on the gate insulating film 77. The gate electrode 79 forms a junction with the gate insulating film 77. This manufacturing method allows providing a transistor having the gate electrode 79 that controls channel carriers via the insulating film 77.

Alternatively, the gate electrode that forms a junction with the first portions 71a of the carrier supply layer 71 can be formed without formation of the gate insulating film 77. This manufacturing method allows providing a transistor in which channel carriers are controlled using a gate electrode that forms a Schottky junction with a semiconductor.

The materials of the channel layer 69 and the carrier supply layer 71 can be any one from among InGaN/AlGaN, GaN/AlGaN and AlGaN/AlN. These can provide suitable combinations of the channel layer 69 and the carrier supply layer 71.

The gallium nitride-based semiconductor of the drift layer 55, the gallium nitride-based semiconductor of the current block layer 57, and the gallium nitride-based semiconductor of the contact layer 59 can be any one from among n-type GaN/p-type GaN/n⁺-type GaN and n-type GaN/p-type AlGaN/n⁺-type GaN. These can provide suitable combinations of the drift layer 55, the current block layer 57 and the contact layer 59.

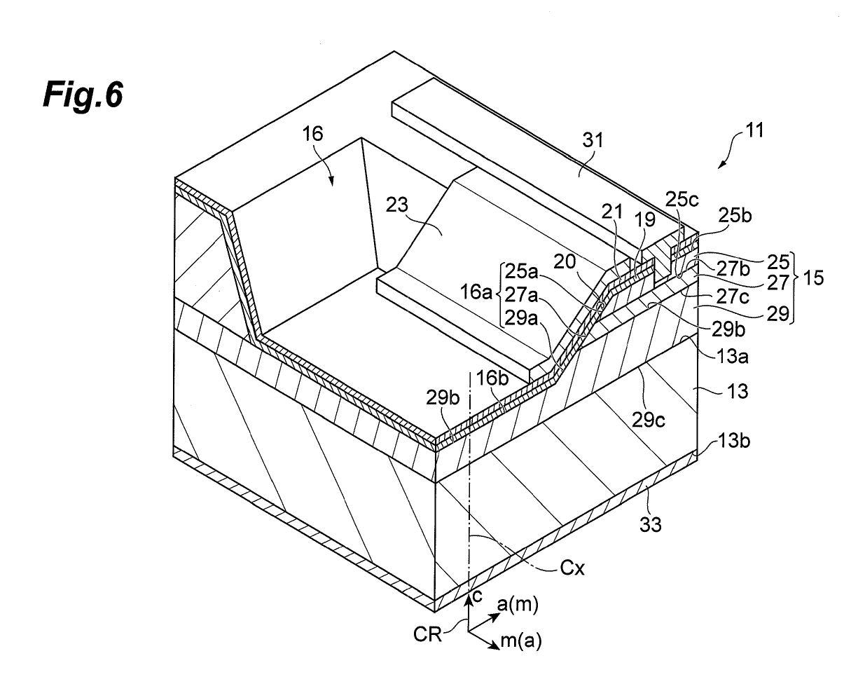

FIG. 6 is a diagram illustrating the structure of a nitride electronic device according to the present embodiment. A heterojunction transistor 11 will be explained as an example of a nitride electronic device. The heterojunction transistor 11 includes a conductive substrate 13, a semiconductor stack 15, a drift layer 17, a channel layer 19, a carrier supply layer 21 and a gate electrode 23. The conductive substrate 13 has a main surface 13 a of a group III nitride and a rear surface 13b of a group III nitride. The group III nitride main surface 13a is preferably a c-plane, and can have a slight off-angle for the purpose of appropriate crystal growth. The semiconductor stack 15 has an opening 16 sunk in the direction of the main surface 13a of the conductive substrate 13. The opening 16 is defined by a mesa, recess or groove formed in the semiconductor stack 15. The channel layer 19 is formed of a gallium nitride-based semiconductor and is provided in the opening 16 of the semiconductor stack 15. The carrier supply layer 21 is formed of a group III nitride semiconductor, is provided in the opening 16 of the semiconductor stack 15 and extends on the channel layer 19 in the opening 16. The gate electrode 23 is provided in the carrier supply layer 21. The carrier supply layer 21 is positioned between the channel layer 19 and the gate electrode 23 in the opening 16. The channel layer 19 and the carrier supply layer 21 form a heterojunction 20. The gate electrode 23 controls the generation of a two-dimensional electron gas along the heterojunction 20.

The semiconductor stack 15 includes a first conductivity type gallium nitride-based semiconductor layer 25, a second conductivity type gallium nitride-based semiconductor layer 27 and a gallium nitride-based semiconductor layer 29. The first conductivity type gallium nitride-based semiconductor layer 25 has, for instance, n conductivity, and is provided on the main surface 13a of the substrate 13. The second conductivity type gallium nitride-based semiconductor layer 27 has for instance p conductivity, and is provided between the first conductivity type gallium nitride-based semiconductor layer 25 and the main surface 13a of the conductive substrate 13. The gallium nitride-based semiconductor layer 29 has for instance n conductivity and is provided on the main surface 13a of the substrate 13. The carrier supply layer 21 and the channel layer 19 extend between the gate electrode 23 and the side surface of the second conductivity type gallium nitride-based semiconductor layer 27.

The first conductivity type gallium nitride-based semiconductor layer 25 has an end surface 25a that is positioned at a side surface 16a of the opening 16 of the semiconductor stack 15. The second conductivity type gallium nitride-based semiconductor layer 27 has an end surface 27a that is positioned at the side surface 16a of the opening 16 of the semiconductor stack 15. The gallium nitride-based semiconductor layer 29 has an end surface 29a that is positioned at the side surface 16a of the opening 16 of the semiconductor stack 15. The channel layer 19 is provided on the end surface 25a of the first conductivity type gallium nitride-based semiconductor layer 25, the end surface 27a of the second conductivity type gallium nitride-based semiconductor layer 27, and the end surface 29a and a top surface 29b of the first conductivity type gallium nitride-based semiconductor layer 29. The drift layer 17 is provided on the end surface 29a of the gallium nitride-based semiconductor layer 29 for insulation, and on the main surface 13a.

In the present example, as illustrated in FIG. 6, the bottom surface 16b of the opening 16 is provided substantially along the c-plane (plane perpendicular to the c-axis). In FIG. 6, a crystal coordinate system CR is depicted wherein a reference axis Cx denotes the direction of the c-axis. The m-plane is a plane perpendicular to the m-axis in the crystal coordinate system CR, and the a-plane is a plane perpendicular to the a-axis in the crystal coordinate system CR. The side surface 16a of the opening 16 is inclined with respect to the a-plane of a group III nitride semiconductor, is inclined with respect to the m-plane of a group II nitride semiconductor, and is inclined with respect to the c-plane of the group III nitride semiconductor. In the present example, the side surface 16a of the opening 16 extends in the direction of the m-axis or a-axis.

The heterojunction transistor 11 may further include a source electrode 31 that is connected to the first conductivity type gallium nitride-based semiconductor layer 25. The source electrode 31 can supply potential to the second conductivity type gallium nitride-based semiconductor layer 27. Upon supply of potential by the source electrode 31 not only to the first conductivity type gallium nitride-based semiconductor layer 25 but also to the second conductivity type gallium nitride-based semiconductor layer 27, the potential of the second conductivity type gallium nitride-based semiconductor layer 27 is applied using the source electrode 31, in the form of back bias. This is suitable for a normally-off operation of the heterojunction transistor 11.

The heterojunction transistor 11 may further include a drain electrode 33 that is provided on the rear surface 13b of the conductive substrate 13. The drain electrode 33 can be isolated from the gate electrode 23, since the drain electrode 33 is provided on the rear surface 13b of the conductive substrate 13. This is accordingly effective in terms of realizing high voltage breakdown. The drain electrode 33 may be formed of, for instance, Ni/Al, and the source electrode 31 may be formed of, for instance, Ti/Al. The gate electrode 23 may be formed of, for instance, Ni/Au, Pt/Au, Pd/Au, Mo/Au or the like.

The first surface 25b of the first conductivity type gallium nitride-based semiconductor layer 25 forms a junction with the channel layer 19. A second surface 25c of the first conductivity type gallium nitride-based semiconductor layer 25 forms a junction with a first surface 27b of the second conductivity type gallium nitride-based semiconductor layer 27. The first surface 29b of the gallium nitride-based semiconductor layer 29 forms a junction with a second surface 27c of the second conductivity type gallium nitride-based semiconductor layer 27. A second surface 29c of the gallium nitride-based semiconductor layer 29 forms a junction with the main surface 13a of the conductive substrate 13.

On the side surface 16a of the opening 16, the rear surface of the channel layer 19 forms a junction with the end surface 25a of the first conductivity type gallium nitride-based semiconductor layer 25. The rear surface of the channel layer 19 forms a junction with the end surface 25a of the first conductivity type gallium nitride-based semiconductor layer 25 and the end surface 27a of the second conductivity type gallium nitride-based semiconductor layer 27. The rear surface of the channel layer 23 forms a junction with the end surface 29a of the gallium nitride-based semiconductor layer 29. The gate electrode 18 forms a Schottky junction with the carrier supply layer 21.

An example of the heterojunction transistor 11 is illustrated below.

Conductive substrate 13: n-type GaN (carrier concentration: 1×10¹⁹ cm⁻³).

Channel layer 19: undoped GaN (carrier concentration: 1×10¹⁵ m⁻³, thickness: 30 nm).

Carrier supply layer 21: undoped AlGaN (thickness: 30 nm, Al composition ratio 0.25).

First conductivity type gallium nitride-based semiconductor layer 25: n-type GaN (carrier concentration:1×10¹⁸ m⁻³, thickness: 0.3 μm).

Second conductivity type gallium nitride-based semiconductor layer 27: p⁺-type GaN (carrier concentration: 1×10¹⁸ m⁻³, thickness: 0.5 μm).

Gallium nitride-based semiconductor layer 29: undoped GaN (carrier concentration: 1×10¹⁵ m⁻³, thickness: 5 μm).

The above heterojunction transistor provides an example of a practicable structure. By virtue of the contribution of the thermal treatment in the predetermined atmosphere, the surface roughness Rms of the surface of the carrier supply layer 21 (or the interface between the carrier supply layer 21 and the upper layer that forms a junction with the carrier supply layer 21) is smaller than the roughness of the interface of the side surface 16a of the opening 16 in the heterojunction transistor. Also, the surface roughness Rms of the surface of the carrier supply layer 21 (or the interface of the carrier supply layer 21 and the upper layer that forms a junction with the carrier supply layer 21) is smaller than the roughness of the interface of the channel layer 19 on the side surface 16a of the opening 16 in the heterojunction transistor.

### EXAMPLE 1

Manufacture of an Epitaxial Substrate

A gallium nitride film is formed by MOCVD. Trimethyl gallium is used as a raw material for gallium. High-purity ammonia is used as a raw material for nitrogen. Purified hydrogen is used as a carrier gas. The purity of high-purity ammonia is 99.999% or higher, and the purity of purified hydrogen is 99.999995% or higher. Hydrogen base silane is used as an n-type dopant, and biscyclopentadienylmagnesium is used as a p-type dopant. A conductive gallium nitride substrate is used as the substrate. The size of the substrate is 2 inches. Firstly, the substrate is cleaned with ammonia in a hydrogen atmosphere at a temperature of 1030° C. and a pressure of 100 Torr. Thereafter, the temperature is raised to 1050° C., and then a gallium nitride layer is formed at a pressure of 200 Torr and a V/III molar ratio of 1500.

A 5 μm-thick n-type drift layer, a 0.5μ-thick p-type current block layer, and a 0.2μm-thick n-type cap layer (contact layer) are grown, in this order, on the gallium nitride substrate. The Si concentration in the drift layer is 1×10¹⁶ cm ⁻³, the Mg concentration in the barrier layer is 1×10¹⁸ cm ⁻³, and the Si concentration in the cap layer is 1×10¹⁸ cm ⁻³. As a result of the above film deposition there is manufactured an epitaxial substrate having a semiconductor stack of npn structure on the gallium nitride substrate.

Manufacture of a Device Structure

An opening section is formed in the epitaxial substrate. A mask for this purpose is manufactured through coating of the epitaxial film surface with a resist, followed by formation of a pattern in the resist by photolithography. An opening section is formed on the epitaxial substrate by reactive ion etching, using this mask, to thereby manufacture a substrate product having an opening.

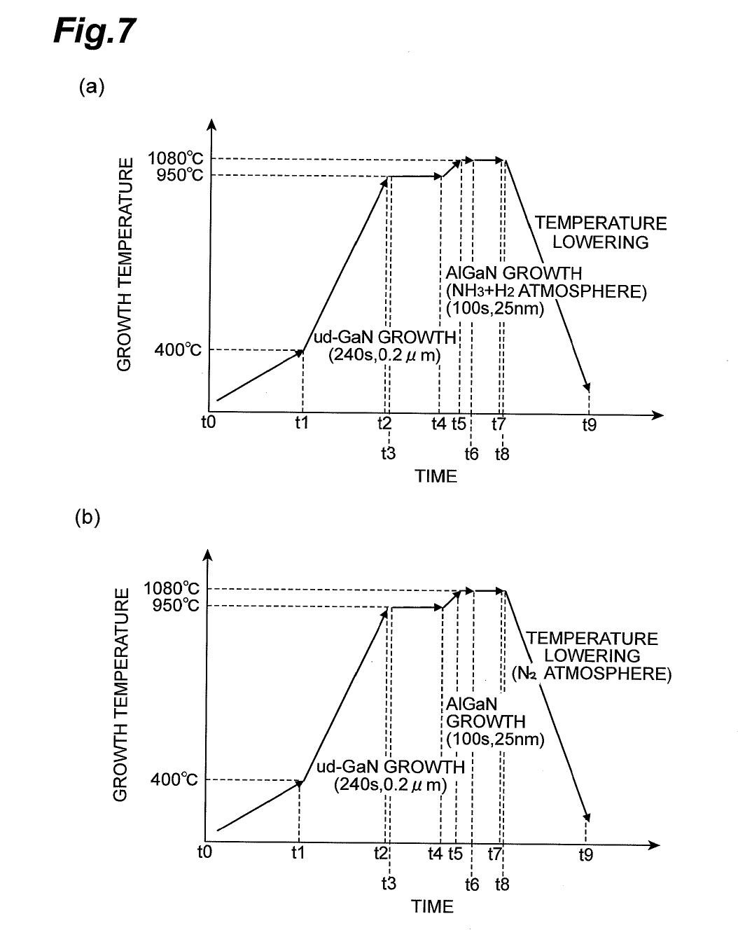

The resist mask is removed and the substrate is cleaned, and thereafter, the substrate is introduced once more into an MOCVD device, and regrowth is performed in accordance with the temperature modification sequence illustrated in FIG. 7. In the sequence of Parts (a) and (b) of FIG. 7, the substrate product is disposed in a growth furnace at time t0; thereafter, the substrate temperature is raised up to 400° C. while under streaming of hydrogen. The substrate temperature reaches 400° C. at time t1. The substrate temperature is further raised up to 950° C. while under streaming of hydrogen and ammonia. The substrate temperature reaches 950° C. at time t2. At time t3 after the substrate temperature is sufficiently stable, trimethyl gallium and ammonia are supplied to the growth furnace, to thereby grow an undoped GaN (i-GaN) film. Supply of trimethyl gallium is stopped at time t4, to stop film deposition. Next, the substrate temperature is further raised up to 1080° C. while under streaming of hydrogen and ammonia. The substrate temperature reaches 1080° C. at time t5. At time t6 after the substrate temperature is sufficiently stable, trimethyl gallium, trimethyl aluminum and ammonia are supplied to the growth furnace, to thereby grow an undoped AlGaN (i-AlGaN) film. Supply of trimethyl gallium and trimethyl aluminum is stopped at time t7, to terminate film deposition.

In the sequence of Part (a) of FIG. 7, lowering of substrate temperature is initiated at time t8 with continued streaming of ammonia and hydrogen also after film deposition has been stopped. Once the substrate temperature has dropped sufficiently, the substrate product is removed from the growth furnace at time t9.

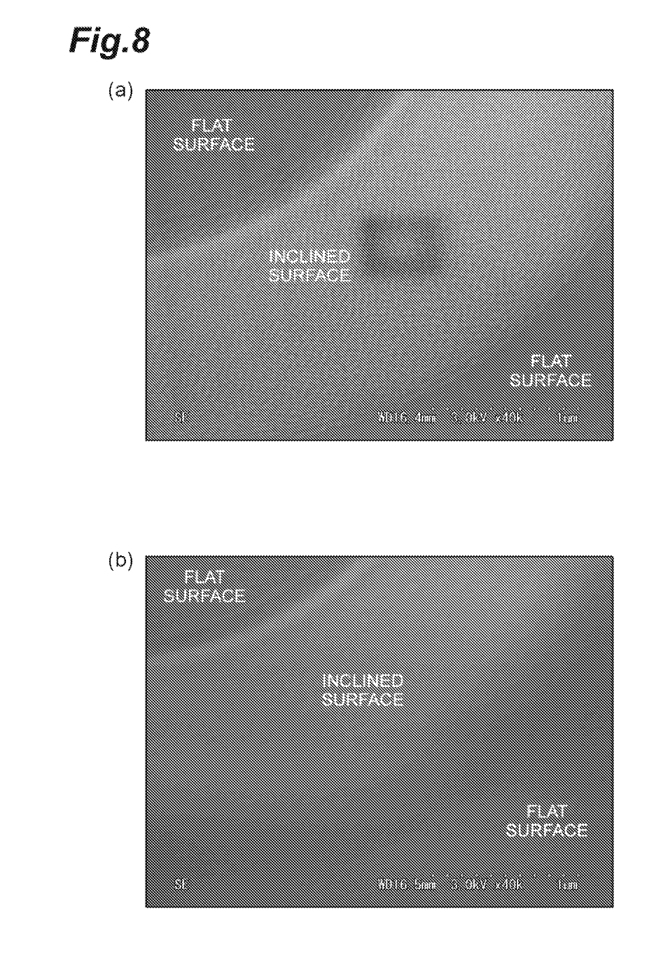

The epitaxial regrowth surface of the substrate product was observed under scanning electron microscopy (SEM). Part (a) of FIG. 8 illustrates a SEM image that depicts an AlGaN surface. The upper left area of Part (a) of FIG. 8 denotes the bottom section of an opening, the lower right area denotes a region outside the opening (top surface of the semiconductor stack), and the band area in between denotes the inclined surface of the opening. The SEM image indicates that surface defects concentrate in the inclined surface section, as compared with flat sections.

In the sequence of Part of FIG. 7, film deposition is stopped, and quickly thereafter supply of ammonia and hydrogen to the growth furnace is stopped, and supply of nitrogen (N₂) is initiated, to change the atmosphere of ammonia and hydrogen in a growth furnace chamber to a nitrogen atmosphere. After an atmosphere consisting essentially of nitrogen has been formed, the substrate temperature starts being lowered at time t8. Once the substrate temperature has dropped sufficiently, the substrate product is removed from the growth furnace at time t9.

In the deposition of the i-GaN film for the channel layer and i-AlGaN film for the carrier supply layer, a V/III molar ratio of the raw materials during growth can be set to range from 500 to 5000, the growth temperature from 900 degrees to 1200° C. and the growth pressure from 50 Torr to 760 Torr, in order to grow a carrier supply layer at high purity while suppressing to some extent intrusion of defects into the inclined surface.

The epitaxial regrowth surface of the substrate product was observed under scanning electron microscopy (SEM). Part (b) of FIG. 8 illustrates a SEM image that depicts an AlGaN surface. The upper left area of Part (b) of FIG. 8 denotes the bottom section of an opening, the lower right area denotes a region outside the opening (top surface of the semiconductor stack), and the band area in between denotes the inclined surface of the opening. A comparison between Parts (a) and (b) of FIG. 8 reveals that forming a nitrogen atmosphere in the growth furnace after film deposition allows improving the surface morphology at the inclined surface (band area) of the opening, between the bottom section of the opening and the bottom section of the opening. As illustrated in Part (b) of FIG. 8, the surface morphology of the inclined surface section is good. Part (b) of FIG. 8 reveals no substantial differences in surface morphology of the bottom section of the opening, and the section between the bottom of the opening and the inclined surface of the opening.

After regrowth of the channel layer and the carrier supply layer, a source electrode and a drain electrode are respectively formed, by photolithography and ion beam deposition, on the front surface (epitaxial surface) and the rear surface (substrate rear surface) of the substrate product, and a gate electrode is formed on the opening section side surface. Alumina (Al₂O₃) having a thickness of 10 nm was used as the gate insulating film.

Polycrystalline silicon nitride (for instance, SiN), silicon oxide (for instance, SiO₂), aluminum oxide (Al₂O₃), aluminum nitride (AlN), hafnium oxide (HfO₂) or the like can be used as the insulating film for the nitride-based semiconductor. Methods that can be resorted to for film deposition include metalorganic chemical vapor deposition (MOCVD), plasma chemical vapor deposition (pCVD), sputtering or atomic layer deposition (ALD). In a case where aluminum oxide and/or silicon oxide are deposited by ALD, a high-purity film having good planarity at the atomic level can be formed at a low temperature, and hence damage to an underlying layer during film deposition can be reduced, and it becomes accordingly possible to reduce the interface-level density at the insulating film/semiconductor junction.

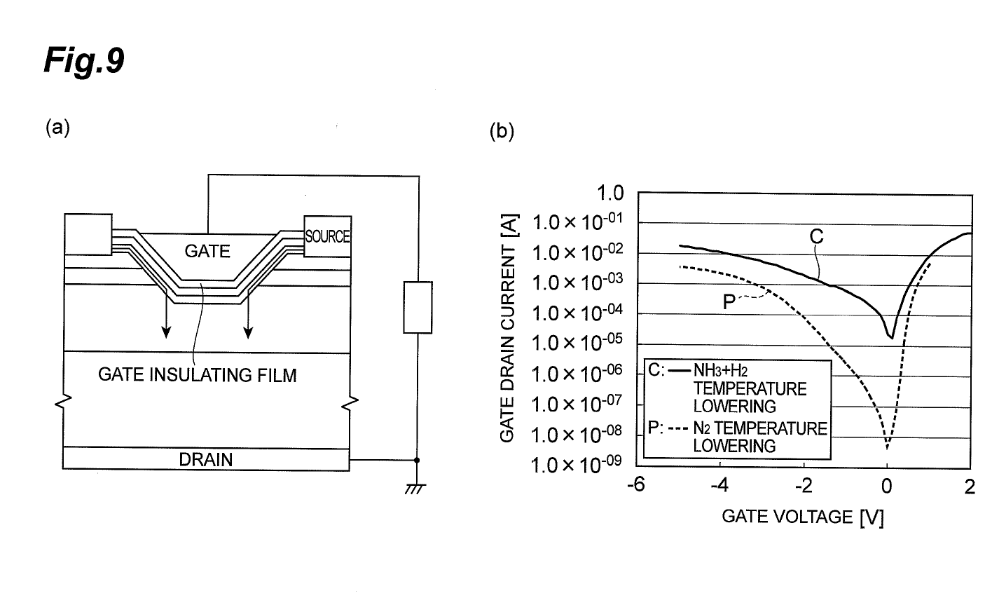

In the above example, current leakage was measured between the gate and drain of the manufactured transistor. Part (a) of FIG. 9 illustrates measurement settings. In the connection of the figure it becomes possible to fix the drain electrode potential and to measure gate-drain current leakage through bias-sweeping of the gate electrode. Part (b) of FIG. 9 illustrates leakage current characteristics P and C. The gate leakage currents differ depending on differences in the atmosphere after growth of the carrier supply layer. Defects in the AlGaN surface at the inclined surface of the opening are reduced by the atmosphere that can supply nitrogen but that does not contain ammonia. Current leakage in the gate electrode can be reduced as a result.

In the present example, a gate electrode is formed on the gate insulating film. To provide a transistor of normally-off operation, it is necessary to deplete the two-dimensional electron gas at the i-AlGaN/i-GaN heterointerface of the inclined surface. This depletion is realized, for instance, by reducing the film thickness of AlGaN. Also, carriers must be induced in the heterointerface through application of gate bias. In a transistor where a Schottky electrode is directly formed on an i-AlGaN surface, forward bias is applied to the Schottky junction in order to induce carriers, and a gate current is generated as a result of this bias application. In order to avoid this gate current and to measure accurately gate currents derived from differences in the surface treatment, the present example does not involve a transistor in which a Schottky electrode is directly formed on an i-AlGaN surface; instead, a gate insulating film is formed on an AlGaN surface, and a gate electrode is formed on this insulating film. Accordingly, the technical contribution of the present embodiment applies as well to transistors having a Schottky gate electrode.

An i-GaN channel layer and an i-AlGaN electron supply layer are regrown, in this order, on the inclined surface in an npn semiconductor stack for a vertical transistor structure that utilizes a conductive substrate. In the formation of this inclined surface, the underlying inclined surface is merely formed through physical shaving by Ar ions during RIE, and crystal planes are not exposed as a result of a chemical treatment in addition to this physical treatment. Accordingly, the surface formed by RIE exhibits larger roughness than atom-scale irregularities. For instance, the surface roughness Rms value of a RIE surface is 2 nm (500 nm square), whereas the surface roughness Rms value of an epitaxial surface, for instance, an epitaxial surface (as-grown surface) of the c-plane, covered by a mask and not subjected to a RIE treatment, is of 0.3 nm (500 nm square). Accordingly, inclined surfaces at openings during growth of the GaN channel layer are rough, and in consequence the surface of the channel layer as well inherits the underlying roughness. Therefore, the AlGaN electron supply layer is grown on a rough surface of the GaN channel layer. The crystal orientation of the inclined surface is tilted from the C-plane, and hence the number of dangling bonds of atoms per unit area in the underlying surface is substantial. Migration of group III atoms (for instance, gallium and aluminum) is accordingly suppressed, and hence the crystal growth mode tends to be an island growth mode. Therefore, surface defects caused by island growth are introduced into the crystal during growth on the inclined surface of the opening. When a gate electrode or gate insulating film is formed on the surface of a III nitride layer having such surface defects, the defects are introduced into the resulting interface or film, and these defects constitute a cause of gate leakage.

The C-plane (Ga-plane) growth surface derived from metalorganic chemical vapor deposition in a nitride semiconductor such as GaN or the like is in a state where the a surface terrace is covered with nitrogen atoms generated from ammonia, such that growth proceeds through adsorption of group III atoms (Ga, Al or the like) onto the surface. In the case of an off-angle substrate, growth proceeds in that group III atoms are taken up in juxtaposed steps, or, alternatively, group III atoms are taken up in island steps, at the C-just surface. During this growth, the density of N atoms that cover the surface is larger in growth where the V/III ratio is large. The adsorption center density of group III atoms increases as a result. Migration is hampered by this increase in adsorption center density, and morphology roughness caused by island growth occurs as a result. As compared with GaN growth, in AlGaN growth Al atoms exhibit a stronger binding force to nitrogen atoms than Ga atoms, and accordingly the migration length of Al atoms is shorter. Therefore, surface defects are likelier to be introduced during growth of a group III nitride that contains Al, than in the case of GaN growth.

Migration of group III atoms such as Al can be promoted by lowering the V/III molar ratio during growth of the group III nitride containing Al, for instance during AlGaN growth. Contamination with carbon impurities from the group III organometallic raw material is significant in metalorganic chemical vapor deposition in growth conditions of lowered V/III molar ratio. Defects associated with deep carrier levels in AlGaN are introduced due to this contamination, and channel mobility is reduced on account of these defects.

In the formation of the device structure according to the present embodiment, ammonia is removed from an atmosphere after growth of an electron supply layer, and preferably nitrogen alone is introduced into the atmosphere. The surface of the group III nitride is exposed to this atmosphere at a temperature not higher than the growth temperature, and a thermal treatment is performed as a result close to the growth temperature, after which the temperature is lowered. Temperature is lowered in an atmosphere that contains nitrogen but does not contain ammonia; as a result, decomposition of the AlGaN layer at the surface is induced, and group III atoms having a lower vapor pressure than that of nitrogen remain on the surface. The surface of the group III nitride exposed to the nitrogen atmosphere takes on a state of being moderately covered with group III atoms, such that migration of the group III atoms is promoted. The surface of the group III nitride is planarized as a result in the thermal treatment during temperature lowering. In a case where an atmosphere of hydrogen alone is provided instead of an atmosphere of nitrogen alone, however, excess decomposition is elicited in the surface of the group III nitride, and surface roughness derived from etching is greater than in the case of an atmosphere of nitrogen alone.

The principle of the present invention has been explained by way of preferred embodiments, but it will be apparent to a person skilled in the art that the configurations and details of the present invention can be modified without departing from that principle. The present invention is not limited to the specific features disclosed in the embodiments. Accordingly, rights are claimed for the scope of the claims and for all modifications and variations that are encompassed within the spirit of the claims.

### INDUSTRIAL APPLICABILITY

As explained above, the present invention provides a method for manufacturing nitride electronic devices that allows reducing gate leakage current.

### REFERENCE SIGNS LIST

10a . . . growth furnace, 11 . . . heterojunction transistor, 13 . . . conductive substrate, 15 . . . semiconductor stack, 16 . . . opening, 19 . . . channel layer, 20 . . . heterojunction, 21 . . . barrier layer, 23 . . . gate electrode, 25 . . . first conductivity type gallium nitride-based semiconductor layer, 27 . . . second conductivity type gallium nitride-based semiconductor layer, 29 . . . gallium nitride-based semiconductor layer for insulation, 31 . . . source electrode, 33 . . . drain electrode, CR . . . crystal coordinate system, 51 . . . group III nitride semiconductor substrate, 53, 53b . . . semiconductor stack, 55 . . . drift layer, 57 . . . current block layer, 57 . . . contact layer, E . . . epitaxial substrate, 63 . . . mask, 65 . . . opening, 65d . . . side surface, 65e . . . bottom surface, R11, R12, R13, R31, R32, R33 . . . reference plane, 69 . . . channel layer, 71 . . . carrier supply layer, 73 . . . source electrode, 77 . . . gate insulating film, 79 . . . gate electrode

1. A method for manufacturing nitride electronic devices, comprising the steps of:
forming a substrate product by arranging a substrate in a growth furnace, and thereafter, supplying a source gas containing ammonia and a group III element to the growth furnace, to thereby grow, at a growth temperature, a carrier supply layer on a channel layer on a main surface of the substrate;
exposing the substrate product to a predetermined atmosphere at a temperature not higher than the growth temperature after growth of the carrier supply layer is complete;
lowering the temperature of the substrate product in the predetermined atmosphere, and removing thereafter the substrate product from the growth furnace; and
forming a gate electrode on the carrier supply layer after removing the substrate product,
wherein the channel layer includes a first portion and a second portion, the first portion extends along a first reference plane that is inclined with respect to the main surface of the substrate and a plane perpendicular to a c-axis of the gallium nitride-based semiconductor of the channel layer, and the second portion extends along a second reference plane that is inclined with respect to the first portion,
the carrier supply layer includes a first portion and a second portion, the first portion is grown on the first portion of the channel layer, and the second portion is grown on the second portion of the channel layer,
the gate electrode is formed on the first portion of the carrier supply layer,
an angle formed by a first axis perpendicular to the first reference plane and the c-axis of the gallium nitride-based semiconductor is larger than an angle formed by a second axis perpendicular to the second reference plane and the c-axis of the gallium nitride-based semiconductor,
the band gap of the group III nitride semiconductor of the carrier supply layer is larger than the band gap of the gallium nitride-based semiconductor of the channel layer,
the predetermined atmosphere contains nitrogen but no ammonia,
the channel layer includes a gallium nitride-based semiconductor, and
the carrier supply layer includes a group III nitride semiconductor.

2. The method for manufacturing nitride electronic devices according to claim 1, further comprising the steps of:
forming a semiconductor stack by growing, on the main surface of the substrate, a drift layer formed of a first gallium nitride-based semiconductor, a current block layer formed of a second gallium nitride-based semiconductor and a contact layer formed of a third gallium nitride-based semiconductor;
forming an opening in a main surface of the semiconductor stack by dry etching; and
growing the channel layer on the main surface of the semiconductor stack and on a surface of the opening of the semiconductor stack,
wherein the opening has a side surface that is inclined with respect to the main surface of the semiconductor stack,
the side surface of the opening includes a side surface of the drift layer, a side surface of the current block layer and a side surface of the contact layer,
the first portion of the channel layer is grown on the side surface of the opening,
the second portion of the channel layer is grown on the main surface of the semiconductor stack,
the gate electrode is formed on the side surface of the current block layer,
the conductivity type of the second gallium nitride-based semiconductor is different from the conductivity type of the first gallium nitride-based semiconductor, and
the conductivity type of the second gallium nitride-based semiconductor is different from the conductivity type of the third gallium nitride-based semiconductor.

3. The method for manufacturing nitride electronic devices according to claim 1, wherein a material of each of the channel layer and the carrier supply layer is any one from among InGaN/AlGaN, GaN/AlGaN and AlGaN/AlN.

4. The method for manufacturing nitride electronic devices according to claim 1, further comprising the step of forming the predetermined atmosphere in the growth furnace while maintaining the temperature of the substrate product at the growth temperature after growth of the carrier supply layer is complete,
wherein the temperature of the substrate product starts being lowered from the growth temperature, after the predetermined atmosphere is provided in the growth furnace.

5. The method for manufacturing nitride electronic devices according to claim 1,
wherein the substrate is formed of a conductive free-standing group III nitride substrate,
a main surface of the free-standing group III nitride substrate is at −20 degrees to +20 degrees with respect to a c-axis of a group III nitride of the substrate, and
the method further comprises the step of forming a drain electrode on a rear surface of the substrate.

6. The method for manufacturing nitride electronic devices according to claim 1, wherein an angle formed by the first reference plane and the second reference plane ranges from 5 degrees to 40 degrees.

7. The method for manufacturing nitride electronic devices according to claim 2, wherein the first gallium nitride-based semiconductor of the drift layer, the second gallium nitride-based semiconductor of the current block layer, and the third gallium nitride-based semiconductor of the contact layer are any one from among n-type GaN/p-type GaN/n⁺-type GaN and n-type GaN/p-type AlGaN/n⁺-type GaN.

8. The method for manufacturing nitride electronic devices according to claim 2, further comprising the step of forming a source electrode on the main surface of the semiconductor stack after the substrate product is removed,
wherein the source electrode supplies potential to the current block layer and the contact layer,
the channel layer and the carrier supply layer form a junction,
a two-dimensional electron gas layer is formed in the junction, and
the source electrode supplies carriers that flow through the channel layer.

9. The method for manufacturing nitride electronic devices according to claim 1, wherein the gate electrode forms a junction with the first portion of the carrier supply layer.

10. The method for manufacturing nitride electronic devices according to claim 1, further comprising the steps of:
forming a gate insulating film on the first portion of the carrier supply layer; and
forming a gate electrode on the gate insulating film,
wherein the gate electrode forms a junction with the gate insulating film.

11. The method for manufacturing nitride electronic devices according to claim 10, wherein the gate insulating film is grown by atomic layer deposition (ALD).
